(19) United States
(12) Patent Application Publication
(10) Pub. No.: US 2002/0116673 A1
(43) Pub. Date: Aug. 22, 2002

(54) Method and apparatus for testing memory

(75) Inventors: R. Dean Adams, St.George, VT (US); Michael R. Ouellette, Westford, VT (US); Jeremy P. Rowland, South Burlington, VT (US)

Correspondence Address: IBM MICROELECTRONICS, INTELLECTUAL PROPERTY LAW, 1000 RIVER STREET, 972 E, ESSEX JUNCTION, VT, 05452, US

(73) Assignee: International Business Machines Corporation, Armonk, NY (US)

(21) Appl. No.: 09/737,225

(22) Filed: Dec. 14, 2000

(51) Int. Cl. G11C 29/00

(52) U.S. Cl. 714/719

(57) ABSTRACT

A method and apparatus for accurately testing the addressing of memory devices having memory sets where the data input and data output have width disparities. The method and apparatus ensure that unique patterns are completely written to and read from the memory set in their entirety, thus ensuring that the memory set is valid.

### BACKGROUND

1. Technical Field of the Present Invention

The present invention generally relates to methods and apparatuses that test memory devices, and more specifically, to memory devices that have a memory set with differing input and output data widths.

2. Background of the Present Invention

The electronic industry is in a state of evolution spurred by the recent changes in technology which have allowed greater functionality in smaller devices. This has resulted in the explosion of new found uses for such small devices (e.g. medical, monitoring etc.), as well as greater functionality in increasingly smaller electronic devices.

The evolution has caused electronic devices to become an inseparable part of our society. Consumers are now buying and demanding electronic devices which are smaller, more powerful, and faster at unprecedented rates. These demands are constantly driving the electronic industry to exceed limitations which were previously considered unsurpassable, and to identify and resolve problems that had been ignored or not realized.

Memory devices are an example of an area where problems and solutions are in perpetual demand. Memory devices typically have one or more sets each having numerous cells for storing data. The testing of such devices via their individual sets and cells is focused on whether data can be stored and retrieved accurately. This testing typically involves alternating between the reading and writing of various patterns to the memory cell (e.g. writing and reading all zeros, all ones, a checkerboard, inverse checkerboard, etc.).

Until recently, virtually all memory sets have maintained equal data width for both reads and writes to the set. In communications and other related environments, a need has arisen to have the ability to write large amounts of data while only retrieving small amounts of such written data. Thus, the creation of memory sets having differing data widths for read and write operations. This new type of memory set has created a unique problem that the industry has failed to realize and/or address. Mainly, that the old methods of pattern testing (e.g. checkerboard and inverse checkboard) do not accurately test these new types of memory sets.

It would, therefore, be a distinct advantage to have a method and apparatus that could test the accuracy of memory sets having differing read and write band widths. The present invention provides such a method and apparatus.

### SUMMARY OF THE PRESENT INVENTION

The present invention is a method and apparatus for testing the addressing of memory sets having differing data widths for inputs and outputs. The method and apparatus ensures that unique patterns are completely written and read in their entirety from the memory set. Thus, validating whether the memory set is accurate.

### BRIEF DESCRIPTION OF THE DRAWINGS

The present invention will be better understood and its numerous objects and advantages will become more apparent to those skilled in the art by reference to the following drawings, in conjunction with the accompanying specification, in which:

FIG. 1 is a diagram illustrating an example of a memory set having differing input to output data widths; and

FIG. 2 is a flow chart illustrating the steps for testing a memory set having differing input to output data widths according to the teachings of the present invention.

### DETAILED DESCRIPTION OF THE PREFERRED EMBODIMENT OF THE PRESENT INVENTION

In the following description, numerous specific details are set forth such as specific word or byte lengths, etc., to provide a thorough understanding of the present invention. However, it will be obvious to those of ordinary skill in the art that the present invention can be practiced with different details. In other instances, well-known circuits have been shown in block diagram form in order not to obscure the present invention in unnecessary detail. For the most part, details concerning timing considerations and the like have been omitted inasmuch as such details are not necessary to obtain a complete understanding of the present invention, and are within the skills of persons of ordinary skill in the relevant art.

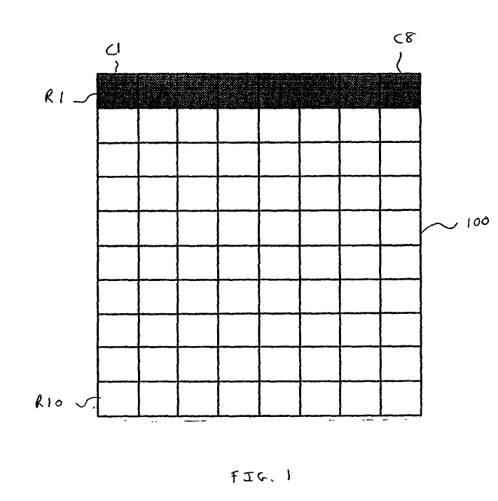

FIG. 1 is a diagram illustrating an example of a memory set 100 having a write data width that is wider than the read data width. In order to better explain the present invention. memory set 100 has been illustrated as having 8 columns (C1-C8) and 10 rows (R1-R10). Memory set 100 has a read data width of 1 bit per cycle and a write data width of 8 bits per cycle. The present invention is not limited to a single memory set having a specific disparity between data widths for reads and writes, but is applicable to any memory device having any number of multiple memory sets (e.g. multi-ported, single ported etc.) having any type of differing data widths for both read and write operations.

Table one below is an example of a typical memory test pattern for testing a memory set such as set 100 by performing the noted steps on all rows (R1-10) and all of the columns in each row (C1-8) starting at the beginning or end and either incrementing (incr) or decrementing (decr).

TABLE ONE

| | |
|---|---|
| Step 1: | Write 0s. (increment) |
| Step 2: | a. Read 0; |
| | b. Write 1; |
| | c. Read 1. (increment) |
| Step 3: | Read 1, Write 0, Read 0. (increment) |
| Step 4: | Read 0, Write 1, Read 1. (decrement) |
| Step 5: | Read 1, Write 0, Read 0. (decrement) |
| Step 6: | Read 0s. |

There is a problem if the above noted memory test pattern of Table one is used on the memory set 100. More specifically, anytime a write operation is performed, the seven remaining read addresses will be overwritten prior to reading the previously written value. In example, during step 1 zeros are written successively to all rows (R1-10) and columns (C1-8) via a total of ten write operations (8 bits per row). During step 2a, you are trying to read all of the zeros previously written from step 1 for each of the rows and columns (i.e. starting with R1). However, because of the nature of the memory set 100 (read data width of 1 bit), during your first read you only read 1 bit (i.e. R1/C1 cell). On the next part step 2b, you write 1s to C1-8 of R1 under the assumption that all reads of the prior write (step 1) have occurred. This assumption would be valid if the read and write data widths of the memory set 100 were equal. Unfortunately, the assumption is incorrect and the testing of memory set 100 is flawed under this test pattern.

The present invention recognizes this invalid assumption and institutes a new method and apparatus for the testing of such a memory set. More specifically, the present invention maintains control over the read addresses during testing and places a unique data type in each cell (R/C) of the memory set. Table two below represents the steps for implementing a test pattern for testing the rows and columns of the memory set 100 according to the teachings of the present invention. It should be noted that the successful testing of any one of the rows (R1-R10) as being valid, necessarily validates the remaining

TABLE TWO
Step 1: Write a “1” to the cell of interest (e.g. R1/C1) and 0s to remaining
cells (e.g. R1/C2-C8).
Step 2: Read a “1” from the cell of interest (e.g. R1/C1) and 0s from
remaining positions (e.g. R1/C2-C8).
- repeat the above steps incrementing the column for the cell of interest
until a “1” value has been written and read from each of the cells in the
row.

Table Three represents a C programming language pseudo code representation of the steps enumerated in Table Two.

```
TABLE THREE
write 0s to the first row (R1)
for cellofinterest = 0..7
{
    write cellofinterest to a “1” with all other data inputs at a “0” to row
    0;
    for cell = 0..7
    {
    if cell == cellofinterest {
      read a “1”}
    else {
      read a “0”
    }
    }
}
```

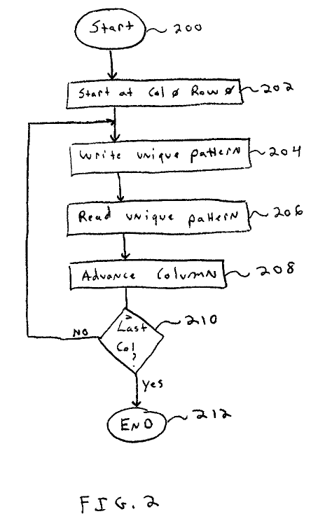

FIG. 2 is a flow chart illustrating the steps for testing a memory set having differing data widths for read and write operations according to the teachings of the present invention. The process for testing such a memory set begins (step 200) by starting at the first row and first cell (step 202) and writing a unique pattern (i.e. a “1” to the cell of interest and “0”s to the remaining cells) (step 204). Alternatively, any row of the memory set could be used, provided a unique a pattern is written to the row as explained herein.

The process then continues to read the unique pattern and ensure that it was actually stored properly (step 206). Obviously, any differences between the read and written pattern would indicate a problem. The process continues by advancing to the next column within the row and repeating the above steps until the last column is reached (steps 208-210). Thereafter, the process proceeds to end at step 218 where reporting of any problems and/or corrections can be made (step 212).

It is thus believed that the operation and construction of the present invention will be apparent from the foregoing description. While the method and system shown and described has been characterized as being preferred, it will be readily apparent that various changes and/or modifications could be made wherein without departing from the spirit and scope of the present invention as defined in the following claims.

What is claimed is:

1. A method of testing a memory set having a data write input, a data read output, a plurality of rows and columns, the data write input having a data width larger than the data width of the data read output, the method comprising the steps of:
selecting one of the plurality of rows;
writing a unique data pattern to a selected cell within the selected row; and
reading the unique data pattern from the selected row.
